(19) United States
(12) Patent Application Publication
(10) Pub. No.: US 2026/0271374 A1
(43) Pub. Date: Sep. 10, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Tomoaki INOKUCHI, Yokohama Kanagawa (JP); Shotaro BABA, Kawasaki Kanagawa (JP); Hiroki NEMOTO, Meguro Tokyo (JP); Yusuke KOBAYASHI, Yokohama Kanagawa (JP); Taichi FUKUDA, Yokohama Kanagawa (JP); Hiro GANGI, Marugame Kagawa (JP); Tatsuya NISHIWAKI, Yokohama Kanagawa (JP); Kentaro ICHINOSEKI, Higashimurayama Tokyo (JP); Hiroki SAKATA, Kawasaki Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/445,719

(22) Filed: Jan. 12, 2026

(30) Foreign Application Priority Data
Mar. 4, 2025 (JP) 2025-033768

(51) Int. Cl. H10D 84/00; H10D 64/00

(52) U.S. Cl. CPC H10D 84/146; H10D 64/117

(57) ABSTRACT

According to one embodiment, a semiconductor device includes first to third electrodes, a semiconductor member, and a first insulating member. The second electrode includes a first electrode portion. The semiconductor member includes a first semiconductor region of a first conductivity type, a second semiconductor region of a second conductivity type, and a third semiconductor region of the first conductivity type. The first semiconductor region includes first to third partial regions At least a part of the second semiconductor region is between the third partial region and the second electrode in the first direction. At least a part of the second semiconductor region is between the third electrode and the first electrode portion in the second direction. The third semiconductor region is between the second semiconductor region and the second electrode. The first electrode portion is in Schottky contact with the semiconductor member.

### CROSS-REFERENCE TO RELATED APPLICATIONS

This application is based upon and claims the benefit of priority from Japanese Patent Application No. 2025-033768, filed on Mar. 4, 2025; the entire contents of which are incorporated herein by reference.

### FIELD

Embodiments described herein relate generally to a semiconductor device.

### BACKGROUND

For example, it is desirable to improve characteristics of semiconductor devices.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating the semiconductor device according to the first embodiment;

FIG. 3 is a schematic cross-sectional view illustrating a semiconductor device according to the first embodiment; and

FIG. 4 is a schematic cross-sectional view illustrating a semiconductor device according to the second embodiment.

### DETAILED DESCRIPTION

According to one embodiment, a semiconductor device includes a first electrode, a second electrode, a third electrode, a semiconductor member, and a first insulating member. The second electrode includes a first electrode portion. A direction from the first electrode to the second electrode is along a first direction. A second direction from the third electrode to the first electrode portion intersects with the first direction. At least a part of the first insulating member is between the third electrode and the semiconductor member. The semiconductor member includes a first semiconductor region of a first conductivity type, a second semiconductor region of a second conductivity type, and a third semiconductor region of the first conductivity type. The first semiconductor region includes a first partial region, a second partial region, and a third partial region. The first partial region is between the first electrode and the third electrode in the first direction. A direction from the first partial region to the second partial region is along the second direction. The second partial region is between the first electrode and the second electrode in the first direction. The third partial region is between the second partial region and the second electrode in the first direction. A direction from a part of the third electrode to the third partial region is along the second direction. At least a part of the second semiconductor region is between the third partial region and the second electrode in the first direction. At least a part of the second semiconductor region is between the third electrode and the first electrode portion in the second direction. The third semiconductor region is between the second semiconductor region and the second electrode. The first electrode portion is in Schottky contact with the semiconductor member.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### (First Embodiment)

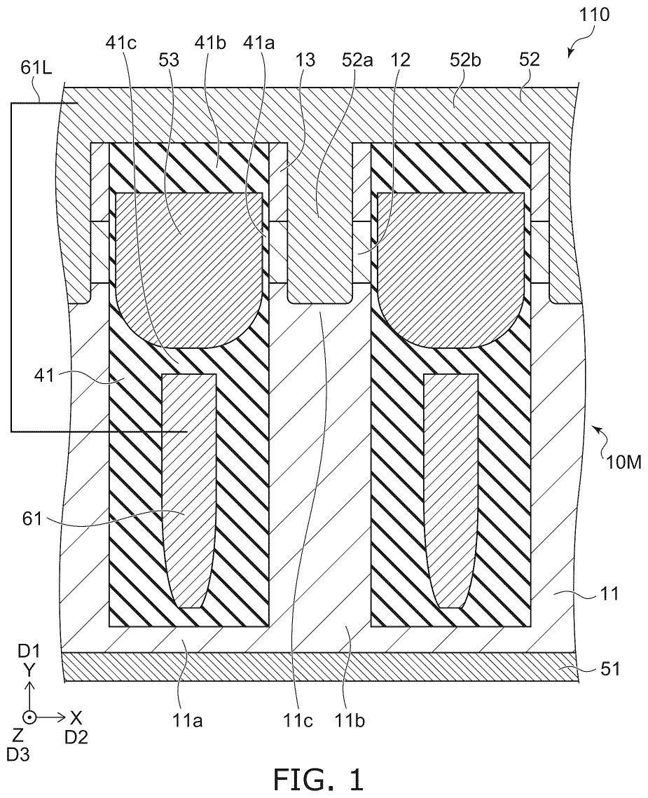

FIG. 1 is a schematic cross-sectional view illustrating a semiconductor device according to a first embodiment.

As shown in FIG. 1, a semiconductor device 110 according to the embodiment includes a first electrode 51, a second electrode 52, a third electrode 53, a semiconductor member 10M, and a first insulating member 41.

The second electrode 52 includes a first electrode portion 52a. A direction from the first electrode 51 to the second electrode 52 is along a first direction D1. The first direction D1 is taken as a Y-axis direction. One direction perpendicular to the Y-axis direction is taken as an X-axis direction. A direction perpendicular to the Y-axis direction and the X-axis direction is taken as a Z-axis direction.

A second direction D2 from the third electrode 53 to the first electrode portion 52a intersects with the first direction D1. The second direction D2 may be, for example, the X-axis direction.

At least a part of the first insulating member 41 is between the third electrode 53 and the semiconductor member 10M. The first insulating member 41 electrically insulates the third electrode 53 from the semiconductor member 10M.

The semiconductor member 10M includes a first semiconductor region 11 of a first conductivity type, a second semiconductor region 12 of a second conductivity type, and a third semiconductor region 13 of the first conductivity type.

For example, the first conductivity type is the n-type and the second conductivity type is the p-type. The first conductivity type may be the p-type and the second conductivity type may be the n-type. In the following example, the first conductivity type is the n-type and the second conductivity type is the p-type.

The first semiconductor region 11 includes a first partial region 11a, a second partial region 11b, and a third partial region 11c. The first partial region 11a is between the first electrode 51 and the third electrode 53 in the first direction D1. A direction from the first partial region 11a to the second partial region 11b is along the second direction D2. The second partial region 11b is between the first electrode 51 and the second electrode 52 in the first direction D1.

The third partial region 11c is between the second partial region 11b and the second electrode 52 in the first direction D1. A direction from a part of the third electrode 53 to the third partial region 11c is along the second direction D2.

At least a part of the second semiconductor region 12 is between the third partial region 11c and the second electrode 52 in the first direction D1. At least a part of the second semiconductor region 12 is between the third electrode 53 and the first electrode portion 52a in the second direction D2.

The third semiconductor region 13 is between the second semiconductor region 12 and the second electrode 52. In this example, the second electrode 52 further includes a second electrode portion 52b. The third semiconductor region 13 is between the second semiconductor region 12 and the second electrode portion 52b in the first direction D1. A part of the third semiconductor region 13 is between a part of the third electrode 53 and a part of the first electrode portion 52a in the second direction D2.

The first electrode portion 52a is in Schottky contact with the semiconductor member 10M. In this example, the first electrode portion 52a is in contact with the first semiconductor region 11. The first electrode portion 52a is in Schottky contact with the first semiconductor region 11.

The current flowing between the first electrode 51 and the second electrode 52 can be controlled by the potential of the third electrode 53. The potential of the third electrode 53 may be, for example, a potential based on the potential of the second electrode 52. The first electrode 51 functions as, for example, a drain electrode. The second electrode 52 functions as, for example, a source electrode. The third electrode 53 functions as, for example, a gate electrode. The semiconductor device 110 is, for example, a transistor.

In the embodiment, the threshold voltage of the semiconductor device 110 can be controlled by the configuration of the second semiconductor region 12. A stable threshold voltage is obtained. For example, variations in the threshold voltage caused by fluctuations in, for example, the manufacturing process can be suppressed.

In the semiconductor device 110, for example, an avalanche phenomenon may occur. Holes generated by the avalanche can be discharged toward the second electrode 52 via the junction by the first electrode portion 52a. Accordingly, a stable operation is obtained. According to the embodiment, a semiconductor device capable of improving characteristics can be provided. Electrons generated by the avalanche are efficiently discharged toward the first electrode 51.

In the embodiment, the channel length can be shortened. Accordingly, the total gate charge amount (Qg) is small. The gate capacitance is small. As a result, high-speed switching is obtained. The loss is small. For example, the gate capacitance (Cg) and the gate-drain capacitance (Cgd) are reduced. Accordingly, the total gate charge amount (Qg) and the gate-drain charge amount (Qgd) are reduced. As a result, the loss of the gate driver can be reduced. For example, switching can be sped up. For example, turn-on loss and turn-off loss can be suppressed.

In the embodiment, for example, the impurity concentration of the second semiconductor region 12 of the second conductivity type may be low. A region of the second conductivity type having a high concentration need not be provided. Accordingly, the width (the length in the second direction D2) of one element region can be shortened. Transistors can be provided with high density. The channel area per unit area can be increased. As a result, for example, the on-resistance can be reduced. A large current can be switched.

In the embodiment, for example, a low forward voltage VF may be obtained in the Schottky diode.

As shown in FIG. 1, a part of the third partial region 11c may be provided between the third electrode 53 and the first electrode portion 52a in the second direction D2. Stable characteristics are easily obtained.

The first electrode portion 52a may include, for example, at least one element selected from the group consisting of Co, Ni, Pt, Ir, Se, Pd, Rh, Re, Mo, V, Ti, W, Ta, Zr, Al, Sn, Os, Nb, Ru, Sr, and Hf, an oxide including the above element, or a nitride including the above element. These materials have high work functions. Holes are stably and efficiently discharged.

In the embodiment, the first electrode portion 52a may include, for example, at least one selected from the group consisting of Se, Pd, Rh, Re, Ta, Zr, Al, Sn, Os, Nb, Ru, Sr, V, and Ru.

As in the example in FIG. 1, in a case where the first electrode portion 52a is in Schottky contact with the first semiconductor region 11 of the first conductivity type (n-type), the first electrode portion 52a may include, for example, at least one element selected from the group consisting of Co, Ni, Pt, Ir, Mo, V, Ti, and W, an oxide including the above element, or a nitride including the above element.

The work function of the first electrode portion 52a may be, for example, 4.2 eV or more. The work function of the first electrode portion 52a may be, for example, 4.5 eV or more. The work function of the first electrode portion 52a may be, for example, 4.8 eV or more. A more stable operation is easily obtained.

In the embodiment, the second semiconductor region 12 need not be in ohmic contact with the first electrode portion 52a. The width of the second semiconductor region 12 along the second direction D2 can be reduced. In the embodiment, for example, the impurity concentration of the second conductivity type in the second semiconductor region 12 may be less than 1×10¹⁹ cm⁻³. The second semiconductor region 12 having stable characteristics is easily obtained.

In the embodiment, the impurity concentration (third impurity concentration) of the first conductivity type in the third semiconductor region 13 is higher than the impurity concentration (first impurity concentration) of the first conductivity type in the first semiconductor region 11. The first impurity concentration is, for example, not less than 1×10¹⁵ cm⁻³ and not more than 2×10¹⁷ cm⁻³. The third impurity concentration is, for example, not less than 1×10¹⁹ cm⁻³ and not more than 1×10²¹ cm³.

The third electrode 53 includes conductive polysilicon. For example, the third electrode 53 may include silicon and at least one element selected from the group consisting of P, As, Sb, B, and Al.

In the embodiment, the third electrode 53 may include n-type silicon. The third electrode 53 includes, for example, a first element and silicon. The first element includes at least one selected from the group consisting of P, As, and Sb. Stable characteristics are easily obtained with the n-type silicon. Manufacturing is easy.

The first insulating member 41 may include a first insulating region 41a. The first insulating region 41a is between the third electrode 53 and the second semiconductor region 12 and between the third electrode 53 and at least a part of the third semiconductor region 13 in the second direction D2.

As described above, the second electrode 52 may further include the second electrode portion 52b. The second electrode portion 52b is connected to the first electrode portion 52a. The third electrode 53 is between the first partial region 11a and the second electrode portion 52b in the first direction D1. For example, the second electrode portion 52b may be in ohmic contact with the third semiconductor region 13. The material of the second electrode portion 52b may be different from the material of the first electrode portion 52a.

The first insulating member 41 may further include a second insulating region 41b. The second insulating region 41b is between the third electrode 53 and the second electrode portion 52b in the first direction D1.

As shown in FIG. 1, the semiconductor device 110 may further include a first conductive member 61. The position (first conductive member position) of the first conductive member 61 in the first direction D1 is between the position (first partial region position) of the first partial region 11a in the first direction D1 and the position (third electrode position) of the third electrode 53 in the first direction D1. In this example, the first conductive member 61 is between the first partial region 11a and the third electrode 53 in the first direction D1.

The first conductive member 61 is configured to be electrically connected to the second electrode 52. In this example, the first conductive member 61 is electrically connected to the second electrode 52 by a wiring 61L.

A part of the first insulating member 41 is between the first conductive member 61 and the third electrode 53 and between the first conductive member 61 and the semiconductor member 10M. For example, the first insulating member 41 includes a third insulating region 41c. The third insulating region 41c is between the first conductive member 61 and the third electrode 53.

The first conductive member 61 functions as, for example, a field plate. Local electric-field concentration is suppressed. A high isolation capability is obtained. Stable characteristics are obtained.

In the embodiment, a plurality of third electrodes 53 may be provided. The plurality of third electrodes 53 are arranged along the second direction D2. The width of an element including one third electrode 53 in the second direction D2 can be kept small. The third electrode 53 and the first conductive member 61 may extend along a third direction D3. The third direction D3 intersects with a plane that includes the first direction D1 and the second direction D2.

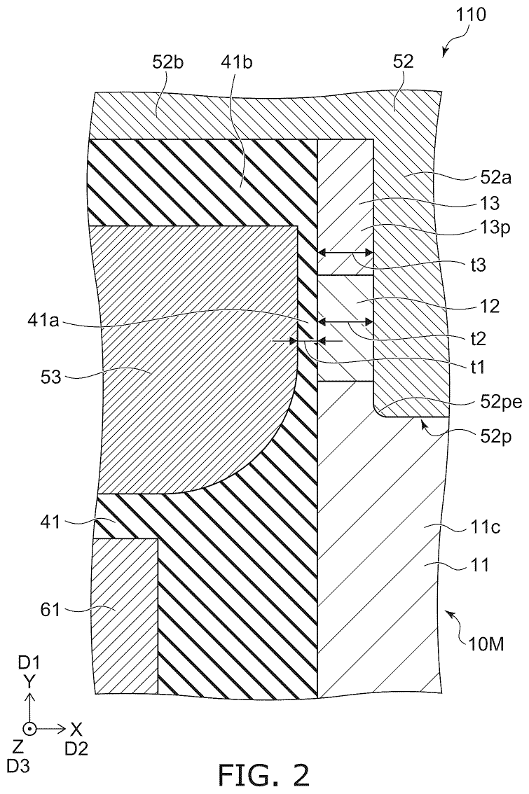

FIG. 2 is a schematic cross-sectional view illustrating the semiconductor device according to the first embodiment.

FIG. 2 is an enlarged view of a part of FIG. 1.

As shown in FIG. 2, the third semiconductor region 13 includes a third semiconductor portion 13p. The third semiconductor portion 13p is between the third electrode 53 and the first electrode portion 52a in the second direction D2. A third semiconductor region thickness t3 of the third semiconductor portion 13p along the second direction D2 is, for example, not less than 5 nm and not more than 100 nm. Stable characteristics are easily obtained.

The thickness of the second semiconductor region 12 along the second direction D2 is taken as a second semiconductor region thickness t2. The second semiconductor region thickness t2 is, for example, not less than 5 nm and not more than 100 nm. Desired characteristics are stably and easily obtained.

The thickness of the first insulating region 41a along the second direction D2 is taken as a first insulating region thickness t1. The first insulating region thickness t1 is, for example, not less than 20 nm and not more than 100 nm. Stable characteristics are easily obtained.

As shown in FIG. 2, the first electrode portion 52a includes a facing portion 52p facing the third partial region 11c. An end portion 52pe of the facing portion 52p in the second direction D2 may be a curved corner portion. The radius of curvature of the end portion 52 pe is, for example, 10 nm or more. The radius of curvature of the end portion 52pe may be, for example, 50 nm or more. For example, stable characteristics are easily obtained. For example, electric-field concentration is suppressed.

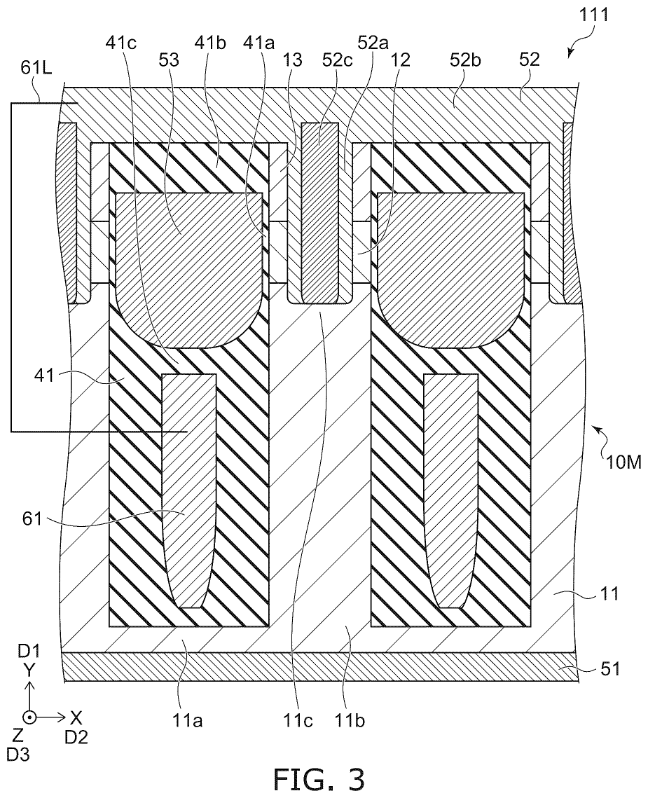

FIG. 3 is a schematic cross-sectional view illustrating a semiconductor device according to the first embodiment.

As shown in FIG. 3, in a semiconductor device 111 according to the embodiment, the configuration of the second electrode 52 is different from that in the semiconductor device 110. The configuration of the semiconductor device 111 may be otherwise similar to the configuration of the semiconductor device 110.

In the semiconductor device 111, the second electrode 52 further includes a third electrode portion 52c in addition to the first electrode portion 52a. The first electrode portion 52a is between the second semiconductor region 12 and the third electrode portion 52c in the second direction D2. For example, a part of the first electrode portion 52a is between a part of the third electrode 53 and a part of the third electrode portion 52c in the second direction D2. The end portion 52pe (see FIG. 2) is included in the first electrode portion 52a and is not included in the third electrode portion 52c. The third electrode portion 52c faces the third partial region 11c and is in contact with the third partial region 11c. The third electrode portion 52c is not in contact with the first partial region 11a.

The first electrode portion 52a may include, for example, at least one element selected from the group consisting of Co, Ni, Pt, Ir, Se, Pd, Rh, Re, Mo, V, Ti, W, Ta, Zr, Al, Sn, Os, Nb, Ru, Sr, and Hf, an oxide including the above element, a nitride including the above element, or a silicide including the above element. The third electrode portion 52c includes, for example, a silicide. The silicide may be, for example, tungsten silicide.

The work function of the third electrode portion 52c is lower than the work function of the first electrode portion 52a. For example, the operating voltage (VF) of the Schottky diode can be reduced. The Schottky diode can be operated before the operation of the p-n diode including the second semiconductor region 12. A stable operation is easily obtained.

### (Second Embodiment)

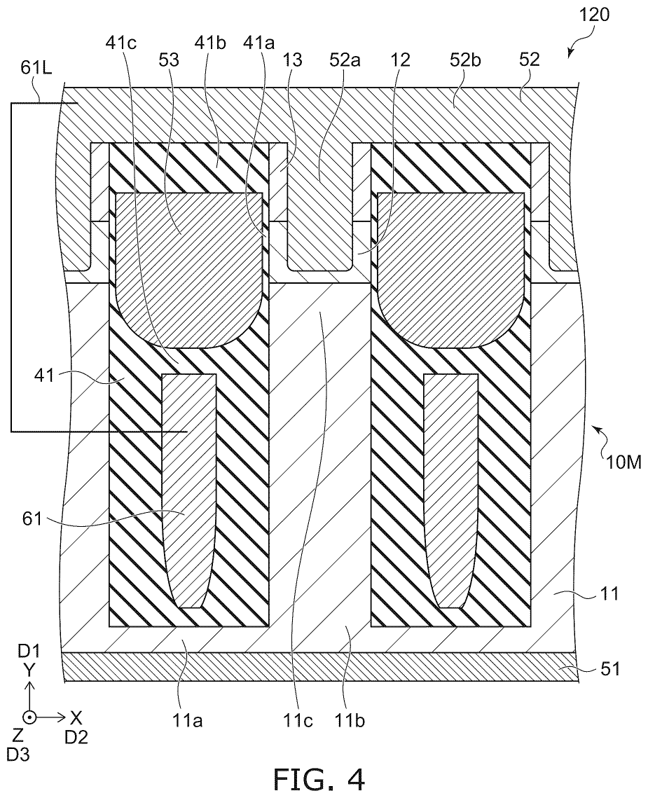

FIG. 4 is a schematic cross-sectional view illustrating a semiconductor device according to the second embodiment.

As shown in FIG. 4, a semiconductor device 120 according to the embodiment also includes the first electrode 51, the second electrode 52, the third electrode 53, the semiconductor member 10M, and the first insulating member 41. In the semiconductor device 120, the configuration of the first electrode portion 52a is different from that in the first embodiment. The configuration of the semiconductor device 120 may be otherwise similar to the configuration of the semiconductor device 110 or the semiconductor device 111 according to the first embodiment.

In the semiconductor device 120, another part of the second semiconductor region 12 is between the third partial region 11c and the first electrode portion 52a in the first direction D1. The first electrode portion 52a is in contact with the other part of the second semiconductor region 12. The first electrode portion 52a is in Schottky contact with the other part of the second semiconductor region 12.

Even in such a configuration, holes generated by avalanche can be discharged toward the second electrode 52 via the Schottky junction by the first electrode portion 52a. Accordingly, a stable operation is obtained. Also in the semiconductor device 120, a semiconductor device capable of improving characteristics can be provided.

Also in the semiconductor device 120, a stable threshold voltage is obtained. Variations in the threshold voltage can be suppressed. The total gate charge amount (Qg) and the gate-drain charge amount (Qgd) are reduced. The loss can be suppressed. High-speed switching is obtained.

Also in the semiconductor device 120, the impurity concentration of the second conductivity type in the second semiconductor region 12 is less than 1×10¹⁹ cm⁻³. The on-resistance can be reduced. A large current can be switched.

In the embodiment, the first conductivity type may be the p-type and the second conductivity type may be the n-type. For example, the embodiment may be applied to a p-channel transistor. In this case, the polarity is reversed in the above description of conduction.

In a case where the first electrode portion 52a is in contact with the second semiconductor region 12 of the second conductivity type (p-type) as in the example of the semiconductor device 120, the first electrode portion 52a may include at least one element selected from the group consisting of Hf, La, Sn, Zr, Mg, V, Ti, Nb, Ta, and W, an oxide including the above element, or a nitride including the above element. In a case where the first electrode portion 52a is in contact with the second semiconductor region 12 of the second conductivity type (p-type), the first electrode portion 52a may include a silicide including the above element. The work function of the first electrode portion 52 a is, for example, 5.1 eV or more. For example, holes are stably and easily discharged.

In the embodiment, the first insulating member 41 may include, for example, a first element and a second element. The first element includes, for example, at least one selected from the group consisting of Si, Al, and Hf. The second element includes, for example, oxygen. The second element may include nitrogen.

In the embodiment, information regarding, for example, the shapes of the semiconductor regions are obtained from, for example, an electron microscope image. Information regarding the compositions and the element concentrations is obtained by, for example, EDX (Energy Dispersive X-ray Spectroscopy) or SIMS (Secondary Ion Mass Spectrometry).

The embodiments may include the following technical proposals.

### (Technical Proposal 1)

A semiconductor device comprising:
a first electrode;
a second electrode including a first electrode portion, a direction from the first electrode to the second electrode being along a first direction;
a third electrode;
a semiconductor member; and
a first insulating member,
a second direction from the third electrode to the first electrode portion intersecting with the first direction,
at least a part of the first insulating member being between the third electrode and the semiconductor member,
the semiconductor member including
   a first semiconductor region of a first conductivity type,
   a second semiconductor region of a second conductivity type, and
   a third semiconductor region of the first conductivity type,
the first semiconductor region including a first partial region, a second partial region, and a third partial region,
the first partial region being between the first electrode and the third electrode in the first direction,
a direction from the first partial region to the second partial region being along the second direction,
the second partial region being between the first electrode and the second electrode in the first direction,
the third partial region being between the second partial region and the second electrode in the first direction,
a direction from a part of the third electrode to the third partial region being along the second direction,
at least a part of the second semiconductor region being between the third partial region and the second electrode in the first direction,
at least a part of the second semiconductor region being between the third electrode and the first electrode portion in the second direction,
the third semiconductor region being between the second semiconductor region and the second electrode,
the first electrode portion being in Schottky contact with the semiconductor member.

### (Technical Proposal 2)

The semiconductor device according to Technical proposal 1, wherein
the first electrode portion is in contact with the first semiconductor region, and
the first electrode portion is in Schottky contact with the first semiconductor region.

### (Technical Proposal 3)

The semiconductor device according to Technical proposal 2, wherein a part of the third partial region is between the third electrode and the first electrode portion in the second direction.

### (Technical Proposal 4)

The semiconductor device according to Technical proposal 2 or 3, wherein the first electrode portion includes at least one element selected from the group consisting of Co, Ni, Pt, Ir, Mo, V, Ti, and W, an oxide including the element, or a nitride including the element.

### (Technical Proposal 5)

The semiconductor device according to any one of Technical proposals 2 to 4, wherein a work function of the first electrode portion is 4.2 eV or more.

### (Technical Proposal 6)

The semiconductor device according to Technical proposal 2 or 3, wherein
the second electrode further includes a third electrode portion,
the first electrode portion is between the second semiconductor region and the third electrode portion in the second direction,
the first electrode portion includes at least one selected from the group consisting of Co, Ni, and Pt, and the third electrode portion includes a silicide.

### (Technical Proposal 7)

The semiconductor device according to Technical proposal 2 or 3, wherein
the second electrode further includes a third electrode portion,
the first electrode portion is between the second semiconductor region and the third electrode portion in the second direction, and
a work function of the third electrode portion is lower than a work function of the first electrode portion.

### (Technical Proposal 8)

The semiconductor device according to any one of Technical proposals 2 to 7, wherein an impurity concentration of the second conductivity type in the second semiconductor region is less than 1×10¹⁹ cm⁻³.

### (Technical Proposal 9)

The semiconductor device according to Technical proposal 1, wherein
another part of the second semiconductor region is between the third partial region and the first electrode portion in the first direction, and
an impurity concentration of the second conductivity type in the second semiconductor region is less than 1×10¹⁹ cm⁻³.

### (Technical Proposal 10)

The semiconductor device according to Technical proposal 9, wherein
the first electrode portion is in contact with the other part of the second semiconductor region, and
the first electrode portion is in Schottky contact with the other part of the second semiconductor region.

### (Technical Proposal 11)

The semiconductor device according to Technical proposal 9 or 10, wherein the first electrode portion includes at least one element selected from the group consisting of Hf, La, Sn, Zr, Mg, V, Ti, Nb, Ta, and W, an oxide including the element, or a nitride including the element.

### (Technical Proposal 12)

The semiconductor device according to any one of Technical proposals 9 to 11, wherein a work function of the first electrode portion is 5.1 eV or more.

### (Technical Proposal 13)

The semiconductor device according to any one of Technical proposals 1 to 12, wherein
the first electrode portion includes a facing portion facing the third partial region, and
a radius of curvature of an end portion of the facing portion in the second direction is 10 nm or more.

### (Technical Proposal 14)

The semiconductor device according to any one of Technical proposals 1 to 13, wherein a second semiconductor region thickness of the second semiconductor region along the second direction is not less than 5 nm and not more than 100 nm.

### (Technical Proposal 15)

The semiconductor device according to Technical proposal 14, wherein
the third semiconductor region includes a third semiconductor portion,
the third semiconductor portion is between the third electrode and the first electrode portion in the second direction, and
a third semiconductor region thickness of the third semiconductor portion along the second direction is not less than 5 nm and not more than 100 nm.

### (Technical Proposal 16)

The semiconductor device according to any one of Technical proposals 1 to 15, further comprising:
a first conductive member,
a first conductive member position of the first conductive member in the first direction being between a first partial region position of the first partial region in the first direction and a third electrode position of the third electrode in the first direction,
the first conductive member being configured to be electrically connected to the second electrode,
a part of the first insulating member being between the first conductive member and the third electrode and between the first conductive member and the semiconductor member.

### (Technical Proposal 17)

The semiconductor device according to any one of Technical proposals 1 to 16, wherein the third electrode includes conductive polysilicon.

### (Technical Proposal 18)

The semiconductor device according to any one of Technical proposals 1 to 16, wherein
the third electrode includes a first element and silicon, and
the first element includes at least one selected from the group consisting of P, As, and Sb.

### (Technical Proposal 19)

The semiconductor device according to any one of Technical proposals 1 to 18, wherein a third impurity concentration of the first conductivity type in the third semiconductor region is higher than a first impurity concentration of the first conductivity type in the first semiconductor region.

### (Technical Proposal 20)

The semiconductor device according to any one of Technical proposals 1 to 19, wherein the second electrode further includes a second electrode portion,
the third electrode is between the first partial region and the second electrode portion in the first direction, and
the second electrode portion is in ohmic contact with the third semiconductor region.

According to the embodiment, a semiconductor device capable of improving characteristics is provided. In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to examples. However, the embodiments of the invention are not limited to these examples. For example, one skilled in the art may similarly practice the invention by appropriately selecting specific configurations of components included in the semiconductor devices such as electrodes, semiconductor members, semiconductor regions, insulating members, etc., from known art. Such practice is included in the scope of the invention to the extent that similar effects thereto are obtained.

Further, any two or more components of the examples may be combined within the extent of technical feasibility and are included in the scope of the invention to the extent that the purport of the invention is included.

Moreover, all semiconductor devices and methods for manufacturing the same practicable by an appropriate design modification by one skilled in the art based on the semiconductor devices and methods for manufacturing the same described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first electrode;
a second electrode including a first electrode portion, a direction from the first electrode to the second electrode being along a first direction;
a third electrode;
a semiconductor member; and
a first insulating member,
a second direction from the third electrode to the first electrode portion intersecting with the first direction,
at least a part of the first insulating member being between the third electrode and the semiconductor member,
the semiconductor member including
a first semiconductor region of a first conductivity type,
a second semiconductor region of a second conductivity type, and
a third semiconductor region of the first conductivity type,
the first semiconductor region including a first partial region, a second partial region, and a third partial region,
the first partial region being between the first electrode and the third electrode in the first direction,
a direction from the first partial region to the second partial region being along the second direction,
the second partial region being between the first electrode and the second electrode in the first direction,
the third partial region being between the second partial region and the second electrode in the first direction,
a direction from a part of the third electrode to the third partial region being along the second direction,
at least a part of the second semiconductor region being between the third partial region and the second electrode in the first direction,
at least a part of the second semiconductor region being between the third electrode and the first electrode portion in the second direction,
the third semiconductor region being between the second semiconductor region and the second electrode,
the first electrode portion being in Schottky contact with the semiconductor member.

2. The semiconductor device according to claim 1, wherein
the first electrode portion is in contact with the first semiconductor region, and
the first electrode portion is in Schottky contact with the first semiconductor region.

3. The semiconductor device according to claim 2, wherein a part of the third partial region is between the third electrode and the first electrode portion in the second direction.

4. The semiconductor device according to claim 2, wherein the first electrode portion includes at least one element selected from the group consisting of Co, Ni, Pt, Ir, Mo, V, Ti, and W, an oxide including the element, or a nitride including the element.

5. The semiconductor device according to claim 2, wherein a work function of the first electrode portion is 4.2 eV or more.

6. The semiconductor device according to claim 2, wherein
the second electrode further includes a third electrode portion,
the first electrode portion is between the second semiconductor region and the third electrode portion in the second direction,
the first electrode portion includes at least one selected from the group consisting of Co, Ni, and Pt, and
the third electrode portion includes a silicide.

7. The semiconductor device according to claim 2, wherein
the second electrode further includes a third electrode portion,
the first electrode portion is between the second semiconductor region and the third electrode portion in the second direction, and
a work function of the third electrode portion is lower than a work function of the first electrode portion.

8. The semiconductor device according to claim 2, wherein an impurity concentration of the second conductivity type in the second semiconductor region is less than 1×10¹⁹ cm⁻³.

9. The semiconductor device according to claim 1, wherein
another part of the second semiconductor region is between the third partial region and the first electrode portion in the first direction, and
an impurity concentration of the second conductivity type in the second semiconductor region is less than 1×10¹⁹ cm⁻³.

10. The semiconductor device according to claim 9, wherein
the first electrode portion is in contact with the other part of the second semiconductor region, and
the first electrode portion is in Schottky contact with the other part of the second semiconductor region.

11. The semiconductor device according to claim 9, wherein the first electrode portion includes at least one element selected from the group consisting of Hf, La, Sn, Zr, Mg, V, Ti, Nb, Ta, and W, an oxide including the element, or a nitride including the element.

12. The semiconductor device according to claim 9, wherein a work function of the first electrode portion is 5.1 eV or more.

13. The semiconductor device according to claim 1, wherein
the first electrode portion includes a facing portion facing the third partial region, and
a radius of curvature of an end portion of the facing portion in the second direction is 10 nm or more.

14. The semiconductor device according to claim 1, wherein a second semiconductor region thickness of the second semiconductor region along the second direction is not less than 5 nm and not more than 100 nm.

15. The semiconductor device according to claim 14, wherein
the third semiconductor region includes a third semiconductor portion,
the third semiconductor portion is between the third electrode and the first electrode portion in the second direction, and
a third semiconductor region thickness of the third semiconductor portion along the second direction is not less than 5 nm and not more than 100 nm.

16. The semiconductor device according to claim 1, further comprising:
a first conductive member,
a first conductive member position of the first conductive member in the first direction being between a first partial region position of the first partial region in the first direction and a third electrode position of the third electrode in the first direction,
the first conductive member being configured to be electrically connected to the second electrode,
a part of the first insulating member being between the first conductive member and the third electrode and between the first conductive member and the semiconductor member.

17. The semiconductor device according to claim 1, wherein the third electrode includes conductive polysilicon.

18. The semiconductor device according to claim 1, wherein
the third electrode includes a first element and silicon, and
the first element includes at least one selected from the group consisting of P, As, and Sb.

19. The semiconductor device according to claim 1, wherein a third impurity concentration of the first conductivity type in the third semiconductor region is higher than a first impurity concentration of the first conductivity type in the first semiconductor region.

20. The semiconductor device according to claim 1. wherein
the second electrode further includes a second electrode portion,
the third electrode is between the first partial region and the second electrode portion in the first direction, and
the second electrode portion is in ohmic contact with the third semiconductor region.
